(19) United States
(12) Patent Application Publication
(10) Pub. No.: US 2005/0121705 A1
(43) Pub. Date: Jun. 9, 2005

(54) Method and apparatus for fabricating semiconductor device

(75) Inventors: Yasuhiro Kawasaki, Osaka (JP); Kenji Yoneda, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 10/989,385

(22) Filed: Nov. 17, 2004

(30) Foreign Application Priority Data
Nov. 19, 2003 (JP) P2003-389262

(51) Int. Cl. H01L 21/44; H01L 21/8234; H01L 29/76; H01L 31/062

(52) U.S. Cl. 257/288; 438/197; 438/303; 257/408

(57) ABSTRACT

A method for fabricating a semiconductor device, wherein a BTBAS—SiN film and an oxide film formed on a reverse-surface side of a semiconductor substrate at the same time as the formation of a BTBAS—SiN film for a side wall or a liner and an oxide film for an offset spacer are completely removed to thereby expose the reverse surface of the semiconductor substrate, and the semiconductor substrate is handled in a process or transfer of the semiconductor substrate by means of an electrostatic chuck or a vacuum chuck as a wafer handler after the reverse surface of the semiconductor substrate is exposed.

### BACKGROUND OF THE INVENTION

1. Field of the Invention

The present invention relates to a method and an apparatus for fabricating a semiconductor device, and more particularly it relates to a technology for preventing generation of particles from a reverse surface of a semiconductor substrate during the fabrication thereof.

2. Description of the Related Art

Conventionally, a SiN film used for an etching stop film, or the like, employs dichlorosilane (SiH₂CI₂), monosilane (SiH₄) or disilane (Si₂H₆) and ammonia (NH3) as material gas and formed (LP—SiN film) in a process at approximately 750° C. and by means of a low-pressure CVD method. However, it has been demanded that a device satisfy an increasingly higher requirement in its design and specification in order to respond to the densification and refinement of the device. In particular, it is demanded that a thermal budget be reduced because it is necessary for dopants to be shallow-jointed in response to a higher-speed circuit operation.

The foregoing trend led to the application of a SiN film (BTBAS—SiN film) employing Tertial Butyl Amino Silane (BTBAS) as a material, which can be formed on a LLD sidewall film or a contact etching stop film at a temperature equal to or below 600° C. (No. 2001-230248 of the Publication of the Unexamined Japanese Patent Applications).

A conventional structure of a reverse surface of a wafer is described referring to FIG. 16, wherein a reference numeral 160 denotes a silicon substrate as a semiconductor substrate, a reference numeral 161 denotes a back seal oxide film, and a reference numeral 162 denotes a BTBAS—SiN film.

On a reverse surface of the silicon substrate 160 is formed the SiN film 162 as a rear-surface barrier film in order to prevent the reverse surface of the silicon substrate 160 from being contaminated by Cu used for a wiring in a wiring step.

A flow of fabricating a conventional MOS transistor is described referring to FIG. 17. In a step S101, an element isolation part is formed on a silicon substrate. In a step S102, the transistor is formed. In a step S103, an inter-layer insulation film is formed. In a step S104, lithography for a first wiring is performed. In a step S105, the wiring is performed. In a step S106, a reverse surface of the silicon substrate is cleaned. In a step S107, lithography for a second wiring is performed. A wiring for a third wiring and thereafter is performed in the same manner.

The BTBAS—SiN film 162 is rather weak compared to the LP—SiN film. Therefore, when the wafer is fixed by means of an electrostatic chuck or a vacuum chuck, the chuck abutting the reverse surface of the wafer may generate cracks in the BTBAS—SiN film 162 on the reverse surface of the wafer. The cracks may reach the back seal oxide film 161, which is a foundation of the silicon substrate 160.

As a result, fragments of the BTBAS—SiN film 162 caused by the cracks may flake away from the reverse surface of the wafer in the lithography step thereafter (step S104) and fall on a wafer disposed immediately below in a wafer housing cassette, and the fragments may result in particles against the wafer.

Further, when the cleaning step (step S106) using a hydrofluoric acid-based agent is included between the wiring step (step S105) and the lithography step (step S107), the ground oxide film is etched by chemicals permeating through the cracks generated in the reverse surface. The fragments of the BTBAS—SiN film 162 break away off in the etching. The removed fragments fall on the wafer disposed immediately below in the wafer housing cassette and may result in the particles against the wafer.

### SUMMARY OF THE INVENTION

A method for fabricating a semiconductor device according to the present invention comprises:
a first step for forming a polysilicon film for a gate electrode on a semiconductor substrate;
a second step for removing a polysilicon film formed on a reverse-surface side of the semiconductor substrate subsequent to the formation of the polysilicon film;
a third step for forming an oxide film for an offset spacer on the semiconductor substrate;
a fourth step for forming a BTBAS—SiN film for at least one of a side wall and a liner on the semiconductor substrate,
a fifth step for removing all of a BTBAS—SiN film and an oxide film formed on the reverse-surface side of the semiconductor substrate and exposing the reverse surface of the semiconductor substrate; and
a sixth step for handling the semiconductor substrate in a process or transfer of the semiconductor substrate by means of a wafer handler after the reverse surface is exposed.

According to a preferable embodiment, in the second step, the polysilicon film formed on the reverse-surface side of the semiconductor substrate at the same time as the formation of the gate polysilicon film is removed.

According to a preferable embodiment, in the fifth step, all of the BTBAS—SiN film and the oxide film formed on the reverse-surface side of the semiconductor substrate at the same time as the formation of the BTBAS—SiN film and the oxide film for the offset spacer are removed to thereby expose the reverse surface of the semiconductor substrate.

According to a preferable embodiment, in the sixth step, the wafer handler is an electrostatic chuck or a vacuum chuck.

According to the present invention, the BTBAS—SiN film and the oxide film on the reverse-surface side of the semiconductor substrate are completely removed to thereby expose the reverse surface of the semiconductor substrate so that the generation of the particles from the reverse-surface side of the semiconductor substrate can be prevented in a following step wherein the electrostatic chuck or the vacuum chuck is used for the process or the transfer of the wafer. As a result, a stable transistor can be fabricated.

### BRIEF DESCRIPTION OF THE DRAWINGS

The present invention is illustrated by way of examples and not limitation in the figures of the accompanying drawings, in which like references indicate similar elements and in which:

FIG. 1 is a flow chart of a gate formation step for describing a first embodiment of the present invention.

FIG. 2A is a sectional view of a wafer after the gate is formed for describing the first embodiment.

FIG. 2B is a sectional view of the wafer after a BTBAS—SiN film and an oxide film on a reverse-surface side of a substrate are removed.

FIG. 3 is a flow chart of a gate formation step for describing a third embodiment of the present invention.

FIG. 4A is a sectional view of a wafer after the gate is formed for describing the third embodiment.

FIG. 4B is a sectional view of the wafer after the BTBAS—SiN film and the like on a reverse-surface side of a substrate are removed.

FIG. 5 is a flow chart of a gate formation step for describing a fourth embodiment of the present invention.

FIG. 6A is a sectional view of a wafer after the gate is formed for describing the fourth embodiment.

FIG. 6B is a sectional view of the wafer after the BTBAS—SiN film and the like on a reverse-surface side of a substrate are removed.

FIG. 7 is a flow chart of an element isolation formation step for describing a fifth embodiment of the present invention.

FIG. 8 is a flow chart of a gate formation step for describing the fifth embodiment.

FIG. 9A is a sectional view of a wafer after the formation of the element isolation and the gate for describing the fifth embodiment.

FIG. 9B is a sectional view of the wafer after the BTBAS—SiN film and the like on a reverse-surface side of a substrate are removed.

FIG. 10 is a sectional side view illustrating a condition wherein particles fall on a wafer immediately below in a cassette according to a conventional method.

FIG. 11 is a sectional side view illustrating a sixth embodiment, which shows a condition inside a cassette.

FIG. 12A is a plane view illustrating an observation of a handling of a wafer by means of a vacuum chuck according to the conventional method from a reverse-surface side of the wafer.

FIG. 12B is a sectional view taken along an A-A line in FIG. 12A.

FIG. 13A is a plane view illustrating an observation of a wafer ready for a handling by means of a support jig according to a seventh embodiment of the present invention from a reverse-surface side of the wafer.

FIG. 13B is a sectional view taken along an A-A line in FIG. 13A, which illustrates a method for transferring the wafer by supporting four corners thereof.

FIG. 14A is a plane view of an observation of how the wafer being processed by means of an electrostatic chuck is retained according to the conventional method from the reverse-surface side of the wafer.

FIG. 14B is a sectional view taken along an A-A line in FIG. 14A.

FIG. 14C is a plane view of an observation of how the wafer being processed by means of the vacuum chuck is retained according to the conventional technology from the reverse-surface side of the wafer.

FIG. 14D is a sectional view taken along an A-A line in FIG. 14C.

FIG. 15A is a plane view illustrating a state where a wafer is mounted on a wafer guide ring according to an eighth embodiment of the present invention.

FIG. 15B is a sectional view taken along an A-A line in FIG. 15A.

FIG. 16 is a schematic illustration of a sectional structure of a typical reverse surface of a Si substrate in the process of diffusion.

FIG. 17 is a flow chart of a fabrication of a conventional MOS transistor.

### DETAILED DESCRIPTION OF PREFERRED EMBODIMENTS OF THE INVENTION

### First Embodiment

Details of the preferred embodiment of the present invention will be described below with reference to drawings.

### First Embodiment

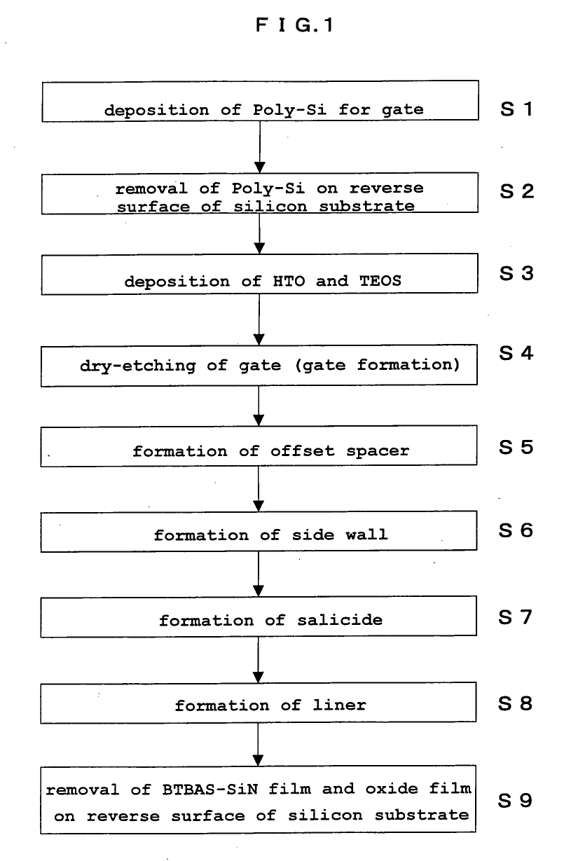

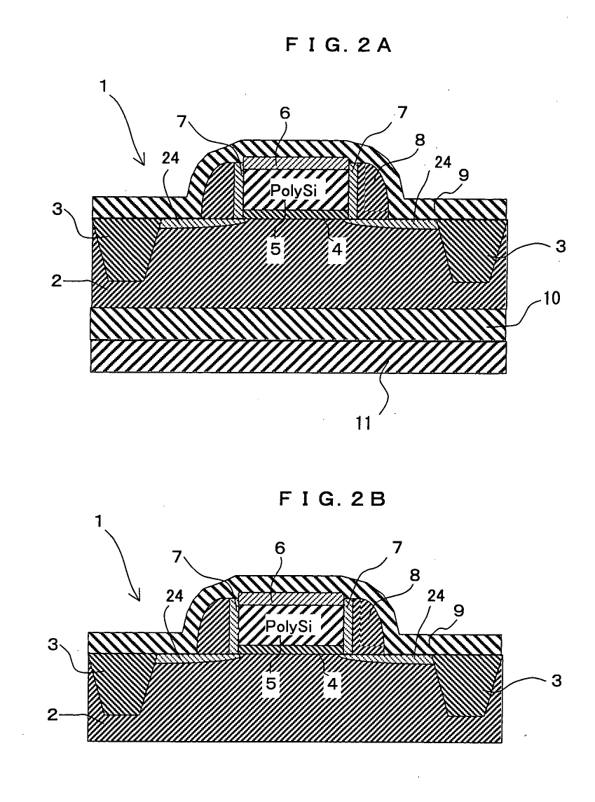

A method for fabricating a semiconductor device according to a first preferred embodiment of the present invention is described referring to FIGS. 1, 2A and 2B.

According to the first embodiment, of low-temperature BTBAS—SiN films applied to a process, a low-temperature BTBAS—SiN film is formed as a liner shown in FIG. 1 in order to reduce the thermal budget, and then, the low-temperature BTBAS—SiN film on a reverse-surface side of a wafer as a semiconductor substrate is completely removed.

As a result of the removal, the generation of particles from the reverse surface of the wafer can be prevented in the subsequent step for transferring the wafer by means of an electrostatic chuck or a vacuum chuck in the case of forming an inter-layer insulation film or the like, which enables a stable transistor to be fabricated.

Referring to the foregoing drawings, in a step S1, 200 nm of polysilicon is deposited on a silicon substrate (wafer) 2, which is an example of semiconductor substrates, via a gate oxide film 4 by means of a low pressure CVD method to thereby form a polysilicon film 5 for agate electrode. A film-formation temperature is set between 620° C. and 650° C.

In a step S2, a polysilicon film formed on a reverse-surface side of the silicon substrate 2 at the same time as the formation of the gate-electrode polysilicon film 5 is removed.

In a step S3, an oxide film made of HTO (high-temperature oxide film) and TEOS (tetraethyl orthosilicate) is deposited as a hard mask in order to form an offset spacer 7 having a structure of a low-density doped drain (LDD).

In a step S4, a gate is finely processed by means of the photolithography technology and dry etching technology.

In a step 5, the offset spacer 7 is formed.

A back seal oxide film and TEOS oxide film may be formed on the reverse-surface side of the silicon substrate 2 before the oxide film for the offset spacer 7 is deposited.

In a step S6, 50-60 nm of a BTBAS—SiN film for a side wall 8 is deposited, and a gate is formed by means of the lithography and dry etching in the same manner as described earlier. A deposition temperature for the BTBAS—SiN film is set between 580° C. and 600° C.

In a step S7, a cobalt silicide 6 is selectively formed in a cobalt silicide step, and the BTBAS—SiN film for a liner 9 is deposited by 30-40 nm.

In a step S8, the deposition temperature for the BTBAS—SiN film is set between 580° C. and 600° C..

FIG. 2A shows a wafer 1 obtained in the foregoing steps.

Referring to reference numerals in FIG. 2A, 2 denotes a silicon substrate, 3 denotes an element isolation part for electrically isolating respective elements, 4 denotes a gate oxide film of a MOS transistor, 5 denotes a gate electrode formed from the polysilocon film, 6 denotes a cobalt silicide, 7 denotes an offset spacer, 8 denotes a side wall, 9 denotes a liner, and 24 denotes a diffusion layer for source/drain formation.

10 denotes a reverse-surface-side oxide film formed from the back seal oxide film, TEOS oxide film, and offset-spacer oxide film, and 11 denotes a BTBAS—SiN film formed on the reverse-surface side of the silicon substrate 2 at the same time as the formation of the side wall 8 and the liner 9.

In a step S9, a wet etching process using a stock solution of hydrofluoric acid (49%) or phosphoric acid boil (thermal phosphoric acid) (160° C.) is performed to the reverse-surface side of the silicon substrate 2 to thereby remove both the BTBAS—SiN film 11 and the reverse-surface-side oxide film 10 and expose the reverse surface of the silicon substrate 2. The state of the exposure is shown in FIG. 2B.

In consequence of performing the foregoing steps, the generation of the particles from the reverse surface of the silicon substrate 2 can be prevented even in the subsequent step for employing the electrostatic chuck or vacuum chuck for the process or transfer of the wafer in the case of forming the inter-layer insulation film or the like. A stable MOS transistor can be fabricated in the foregoing state.

### Second Embodiment

A method for fabricating a semiconductor device according to a second preferred embodiment of the present invention is described.

The steps S1-S8 recited in the first embodiment are also performed in the method according to the second embodiment. In steps thereafter, however, Cu is diffused from the reverse surface of the silicon substrate 2 thereby causing an adverse influence on a performance of the MOS transistor if the method according to the first embodiment, wherein only the BTBAS—SiN film 11 is removed, is followed.

Unlike the fabricating method according to the first embodiment, the second embodiment is characterized in that only the BTBAS-FiN film 11 is removed from the reverse-surface side of the silicon substrate 2 by means of the wet etching process using the stock solution of hydrofluoric acid (49%) or phosphoric acid boil (thermal phosphoric acid) (160° C.), and the reverse-surface-side oxide film 10 is kept to be used as a barrier film for preventing the diffusion of Cu from the reverse surface to the silicon substrate 2 in the wiring step. In consequence of performing the foregoing step, the generation of the particles from the reverse surface of the silicon substrate 2 can be prevented even in the subsequent step for using the electrostatic chuck or vacuum chuck for the process or transfer of the wafer in the case of forming the inter-layer insulation film or the like, and the diffusion of Cu from the reverse surface of the silicon substrate 2 can also be prevented to thereby fabricate a stable MOS transistor.

### Third Embodiment

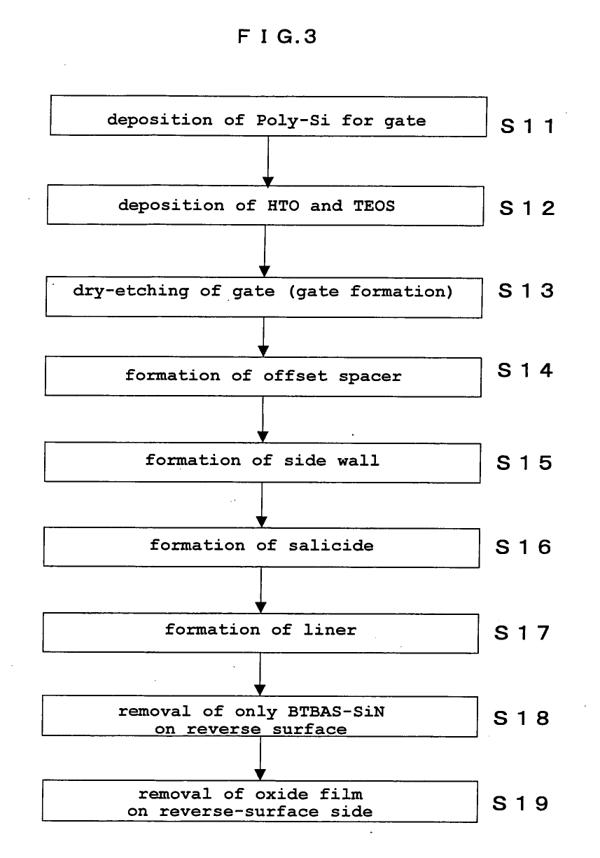

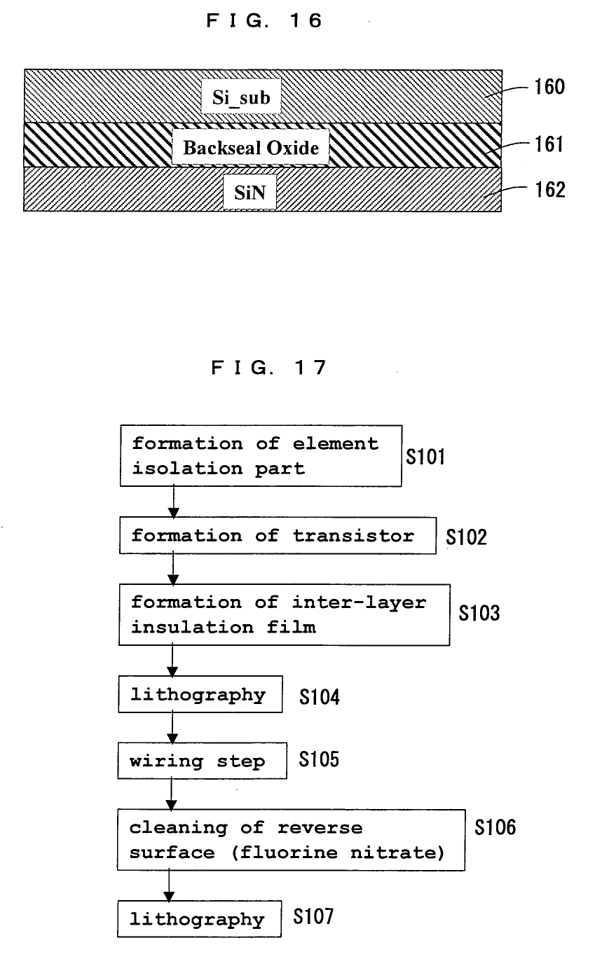

A method for fabricating a semiconductor device according to a third preferred embodiment of the present invention is described referring to FIGS. 3, 4 and 16.

In a step S11, the gate polysilicon film 5 is deposited.

In steps S12-S17, there is no removal of a polysilicon film 12 on the reverse-surface side of the silicon substrate 2, the same steps as the before-mentioned steps S3-S8 are performed.

In a step S18, the BTBAS—SiN film 11 on the reverse surface of the silicon substrate 2 is removed.

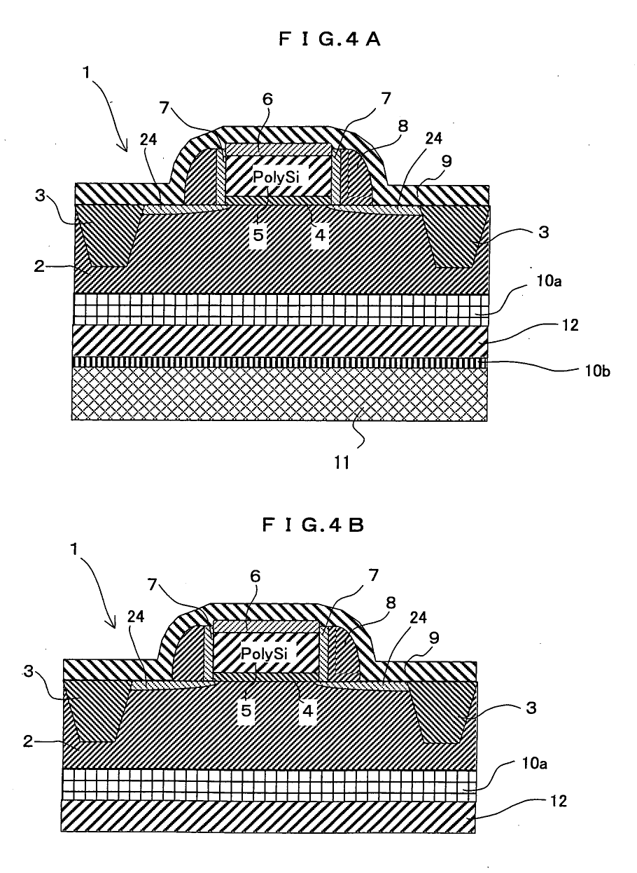

Referring to reference symbols in FIG. 4A, 10a denotes a back seal oxide film, 12 denotes a polysilicon film, and 10b denotes a reverse-surface-side oxide film (formed from TEOS oxide film and offset spacer oxide film).

In a step S19, the wet etching process (160° C.) using the stock solution of hydrofluoric acid (49%) or phosphoric acid boil (thermal phosphoric acid) (160° C.) is performed to the reverse-surface side of the silicon substrate 2 to thereby remove the reverse-surface-side oxide film 10b and expose the polysilicon film 12 as shown in FIG. 4B.

In the removal of the BTBAS—SiN film 11 according to the third embodiment, only the BTBAS—SiN film 11 and the reverse-surface-side oxide film 10b are selectively etched because the polysilicon film 12 has a higher etching resistance against hydrofluoric acid, thereby leaving the polysilicon film 12 and the back seal oxide film 10a.

### Fourth Embodiment

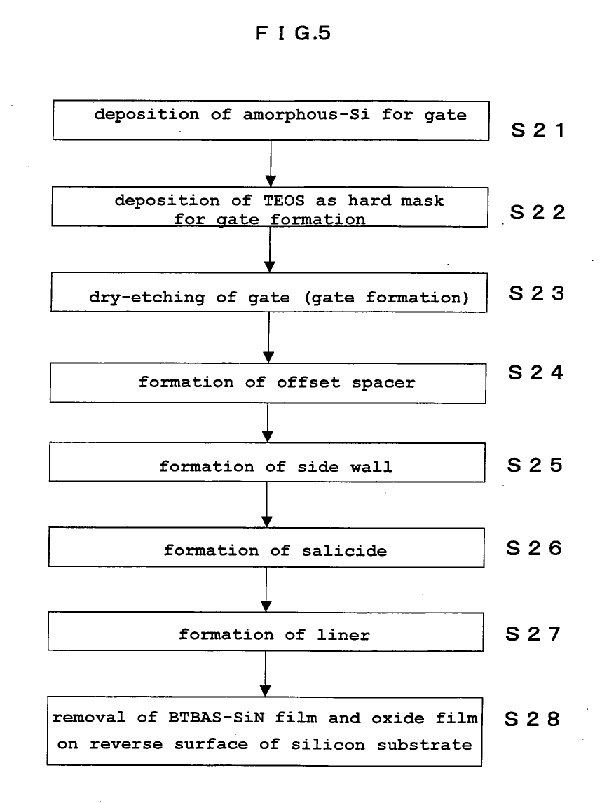

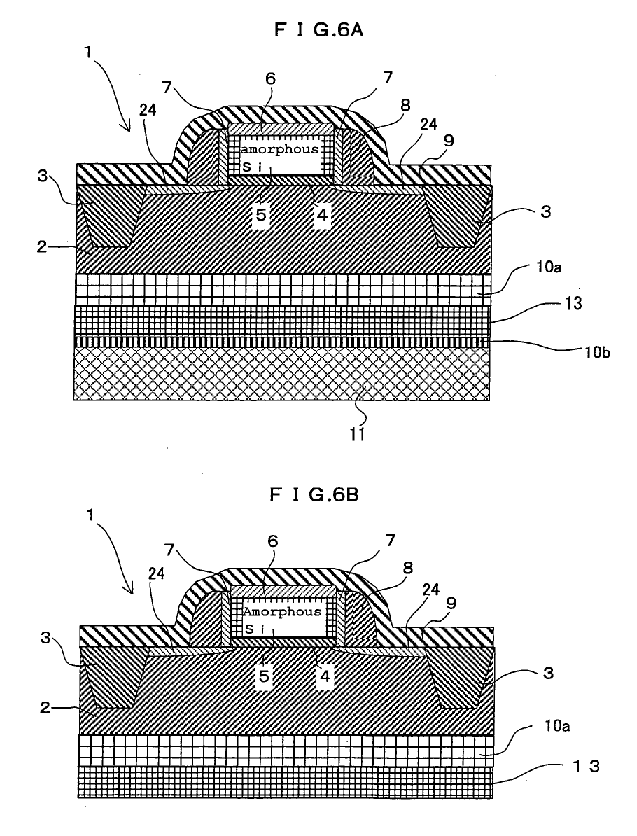

A fourth preferred embodiment of the present invention is described referring to FIGS. 5, 6 and 16. FIG. 6A is a sectional view of a wafer after the formation of the gate. FIG. 6B is a sectional view of the wafer after the removal of the BTBAS—SiN film, and the like, on the reverse-surface side of the silicon substrate.

In the fourth embodiment, the gate electrode 5 is formed using amorphous Si. In using hydrofluoric acid to remove the BTBAS—SiN film 11 on the reverse-surface side of the silicon substrate 2 in the fabricating method according to the third embodiment, the hydrofluoric acid permeates through the exposed polysilicon film 10b, and the back seal oxide film 10a is thereby etched and break away as fragments. As a result, the removed fragments unfavorably cause the particles.

Therefore, according to the fourth embodiment, the BTBAS-Sin film 12 on the reverse-surface side of the silicon substrate 2 is removed so that an amorphous Si film 13 on the reverse-surface side of the silicon substrate 2 is exposed. Thus, the permeation of the hydrofluoric acid is prevented, thereby preventing the generation of the particles.

In a step S21 shown in FIG. 5, a gate amorphous Si 6 is deposited. Steps S22-S28 thereafter are same as the steps S3-S9.

### Fifth Embodiment

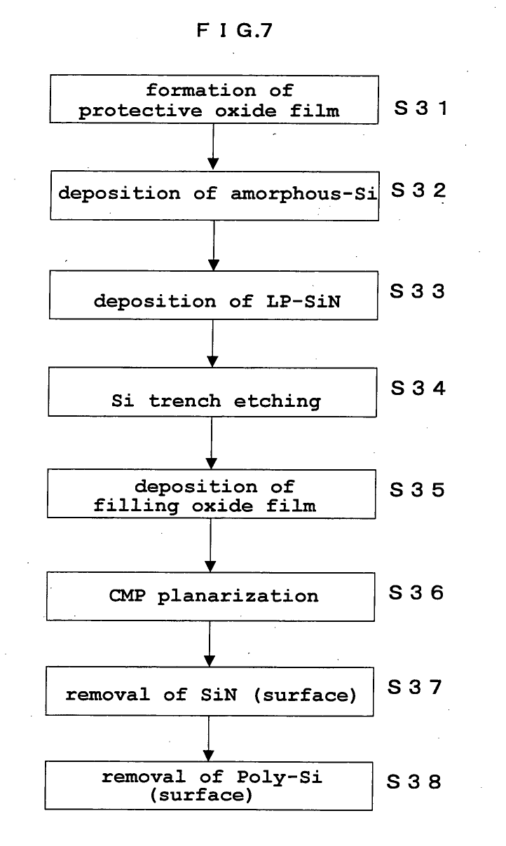

A method for fabricating a semiconductor device according to a fifth preferred embodiment of the present invention is described referring to FIGS. 7 through 9 and FIG. 17.

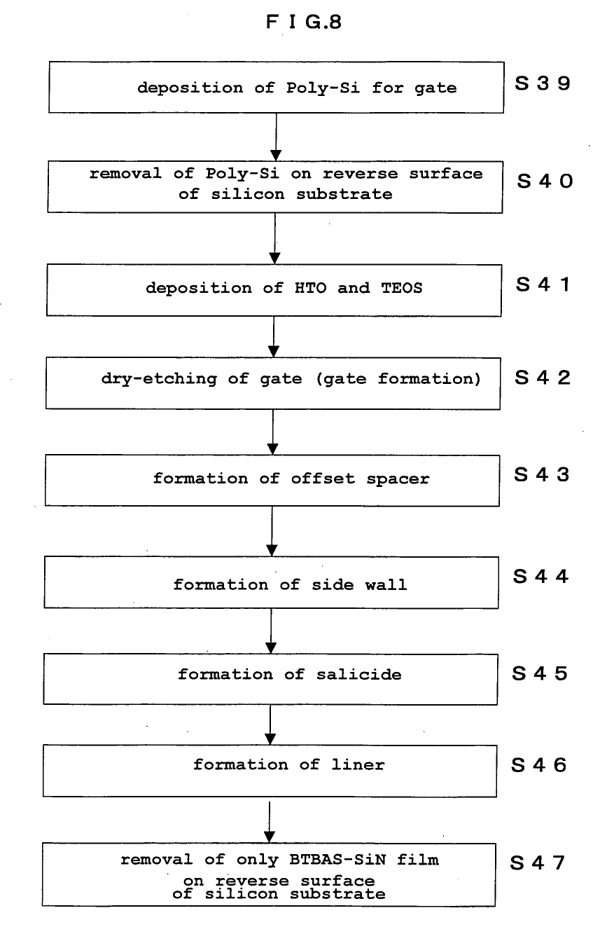

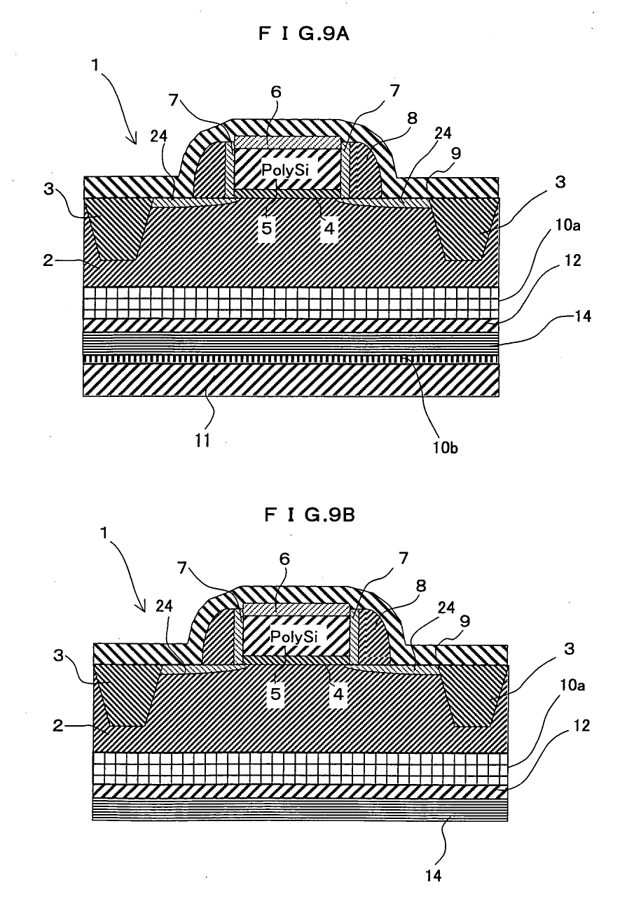

FIGS. 7 and 8 are flow charts. FIG. 9A is a sectional view of a wafer after the formation of the element isolation and gate. FIG. 9B is a sectional view of the wafer after the removal of the BTBAS—SiN film, and the like, on the reverse-surface side of the substrate.

In a step S31, a protective oxide film is formed on the silicon substrate by means of thermal oxidization.

In a step S32, an amorphous silicon film is formed on the protective oxide film by means of an LP-CVD method.

In a step S33, an LP—SiN film for the element isolation is formed on the amorphous silicon film by means of the LP-CVD method. The LP—SiN film is formed at a temperature of 700° C. -800° C., and the amorphous silicon film is thereby poly-siliconized.

In a step S34, after a resist mask for forming the element isolation part is formed on the LP—SiN film, the LP—SiN film, polysilicon film, protective oxide film, and silicon substrate are sequentially etched by means of the dry etching to thereby form a trench on the silicon substrate 2.

In a step S35, the resist mask is removed, and a CVD oxide film is formed by means of a CVD method so as to fill the trench.

In a step S36, the CVD oxide film is planarized by means of CMP to thereby form an element isolation film filling the trench.

In steps S37 and S38, only the LP—SiN film and the polysilicon film on the surface of the silicon substrate are removed by means of the wet etching.

Next, the protective oxide film on the silicon substrate is removed, and then, the gate oxide is formed on the silicon substrate by means of the thermal oxidization.

In a step S39, the gate-electrode polysilicon film is formed on the gate oxide film.

In a step S40, only the polysilicon film formed on the reverse-surface side of the silicon substrate is removed by means of the wet etching.

In a step S41, an TEOS film is formed on the polysilicon film by means of the CVD in order to form a hard mask for the gate formation.

In a step S42, the TEOS film is dry-etched by means of the resist mask. Then, after the resist mask is removed, the TEOS film is dry-etched. Then, after the resist mask is removed, the TEOS film is used as the hard mask to thereby dry-etch the polysilicon film and form the gate electrode.

In a step S43, the CVD oxide film is formed on the silicon substrate by means of the CVD in order to form the LDD offset spacer, and then, the CVD oxide film is etched by means of an anisotropic dry etching to thereby form the offset spacer on the side face of the gate electrode.

In a step S44, the gate electrode and the offset spacer 7 are used as masks to ion-implant an impurity atom to thereby form a low-density LDD layer in the source/drain region. Next, the BTBAS—SiN film is formed on the silicon substrate by means of the CVD in order to form the BTBAS—SiN side wall 8. Thereafter, the BTBAS—SiN film is etched by means of the anisotropic dry etching to thereby form the side wall 8 on the offset spacer 7 on the side face of the gate electrode.

In a step S45, the gate electrode and the side wall are used as the masks to ion-implant the impurity atom to thereby engage a high-density source/drain layer. Next, a cobalt film is formed on the semiconductor substrate by means of sputtering in order to form the cobalt silicide and then annealed by RTA, as a result of which the polysilicon film and the cobalt film are reacted to thereby form a cobalt silicide layer on the gate electrode.

In a step S46, only the unreacted cobalt film is removed by means of the wet etching. Thereafter, a low-temperature BTBAS—SiN film for the liner is formed on the silicon substrate by means of the CVD, the state of which is shown in FIG. 9A.

Referring to reference symbols in FIG. 9A, 2 denotes a silicon substrate, 3 denotes an element isolation part, 4 denotes a gate oxide film, 5 denotes a gate electrode, 7 denotes an offset spacer, 8 denotes a side wall, 9 denotes a liner, 10a denotes a back seal oxide film, 10b denotes an oxide film (TEOS oxide film and LDD offset spacer oxide film), 11 denotes a BTBAS—SiN film, 12 denotes an oxide film, 14 denotes Lp—SiN film, and 24 denotes a diffusion layer.

In a step S47, the wet etching process using the stock solution of hydrofluoric acid (49%) or phosphoric acid boil (thermal phosphoric acid) (160° C.) is performed to the reverse-surface side of the silicon substrate 2 to thereby remove the BTBAS—SiN film 11 and the oxide film 10b formed together with the TEOS oxide film and LDD offset spacer oxide film so that the LP—SiN film 14 formed on the reverse-surface side of the silicon substrate 2 is exposed. The state of the exposure is shown in FIG. 9B.

The fifth embodiment is characterized in that only the surfaces of the LP—SiN film for the element isolation and the Poly-Si film shown in FIG. 7 are removed. The LP—SiN film 14 for the element isolation formed on the reverse-surface side of the silicon substrate 2 is used as a protective film in removing the BTBAS—SiN film 11, wherein the problems included in the first and fourth embodiments can be solved.

Compared to the first embodiment, the method according to the present embodiment is advantageous in preventing the diffusion of Cu from the reverse surface to the silicon substrate 2.

Compared to the second embodiment, the LP—SiN film has twice or more as a high resistance as that of the BTBAS—SiN film by an etching rate with respect to hydrofluoric acid. Therefore, the etching can be substantially selectively performed.

Compared to the third embodiment, chemicals cannot possibly permeate through a foundation because the SiN film is not formed from crystal of a grain size unlike the Poly-si film.

Compared to the fourth embodiment, when amorphous Si is crystallized to the grain size in the poly-Si film by means of a heat treatment for activating the source/drain after the gate is formed, the chemicals permeate through a grain boundary as a result of cleaning the reverse surface (fluorine nitrate) in the wiring step. Then, it is possible for the same problem as in the third embodiment to occur. However, the method, wherein the LP—SiN film is left on the reverse surface of the silicon substrate 2, eliminates the possibility.

In the LP—SiN film shown in FIG. 7, the Sin film is formed using SiH₄, Si₂H₆ or SiH₂Cl₂ and NH₃ as material gas at a deposition temperature between 700° C. and 800° C.

### Sixth Embodiment

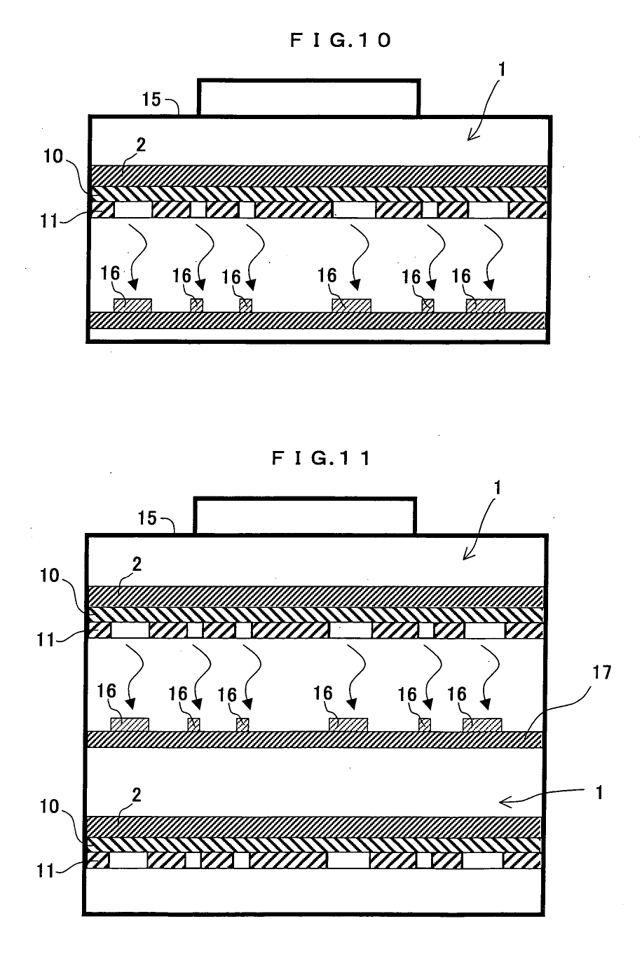

A method for fabricating a semiconductor device according to a sixth preferred embodiment of the present embodiment is described referring to FIGS. 10 and 11.

According to the conventional method, as shown in FIG. 10; when the electrostatic chuck or vacuum chuck is used for fixing or transferring the wafer 1 being processed with the BTBAS—SiN film 11 exposed on the reverse surface thereof after the BTBAS—SiN film is deposited, cracks are generated in the BTBAS-Sin film 11 and the fragments 16 of the BTBAS—SiN film 11 peeled off by the cracks fall on another wafer immediately below resulting in the particles. A reference numeral 10 denotes a reverse-surface-side oxide film.

According to the six embodiment, as shown in FIG. 11, the wafer 1 and a dummy wafer 17 as a dummy substrate are alternately mounted in the cassette in the step using the electrostatic chuck or vacuum chuck when the BTBAS—SiN film 11 is exposed so that the particles formed from the fragments 16 peeled off the BTBAS—SiN film 11 on the reverse surface of the wafer 1 are received by the dummy wafer 17 disposed immediately below. Thus, it can be avoided that the particles fall another wafer 1 further below.

After the foregoing steps are completed, the reverse surface is cleaned by means of a scrubber cleaning to thereby remove the BTBAS—SiN film 11 easily constituting the falling particles due to the cracks generated therein, and the subsequent steps follow.

### Seventh Embodiment

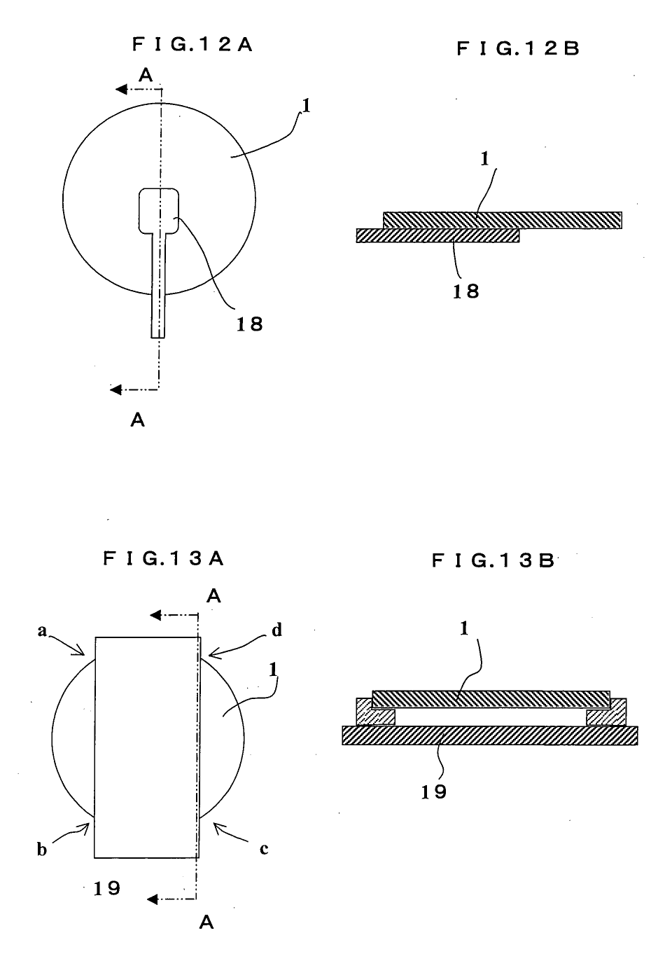

A method for fabricating a semiconductor device according to a seventh preferred embodiment of the present invention is described referring to FIGS. 12 and 13.

In the conventional method, as shown in FIGS. 12A and 12B, a handling is performed in the state where near the center of the reverse surface of the wafer 1 as the semiconductor substrate is held being chucked by means of a vacuum chuck 18. In such a case, the vacuum chuck 18 and the BTBAS—SiN film on the reverse-surface side abut each other, which generates the cracks in the BTBAS—SiN film. Then, the fragments peeled off the BTBAS-Sin film on the reverse-surface side of the wafer 1 when the wafer 1 is released from the vacuum chuck 18 inconveniently fall on another wafer 1 resulting in the particles.

According to the seventh embodiment, as shown in FIGS. 13A and 13B, four corners of the wafer 1, which are four positions a, b, c and d distant from one another in a peripheral end of the wafer 1, are supported by means of a support jig 19 (for example, supported being chucked inward in a plane direction of the wafer, or the like). Thus, the wafer 1 can be transferred causing no damage to the BTBAS—SiN film on the reverse surface of the wafer 1 (particularly, near the center) by carrying the jig 19 by a normal pressure (vacuum adsorption is not employed). Thereby, the generation of the particles from the reverse surface in the transfer process can be prevented.

The supported positions a, b, c and d correspond to peaks of a rectangle inscribing an outer periphery of the wafer 1 having a circular shape in plane view. As shown in FIG. 13B, there is a space provided between the reverse surface of the wafer 1 and the support jig 19, and the wafer 1 is supported only at the four corners thereof. In the described manner, the reverse surface of the wafer 1 is exposed to minimal contacts, thereby preventing the generation of the particles.

### Eighth Embodiment

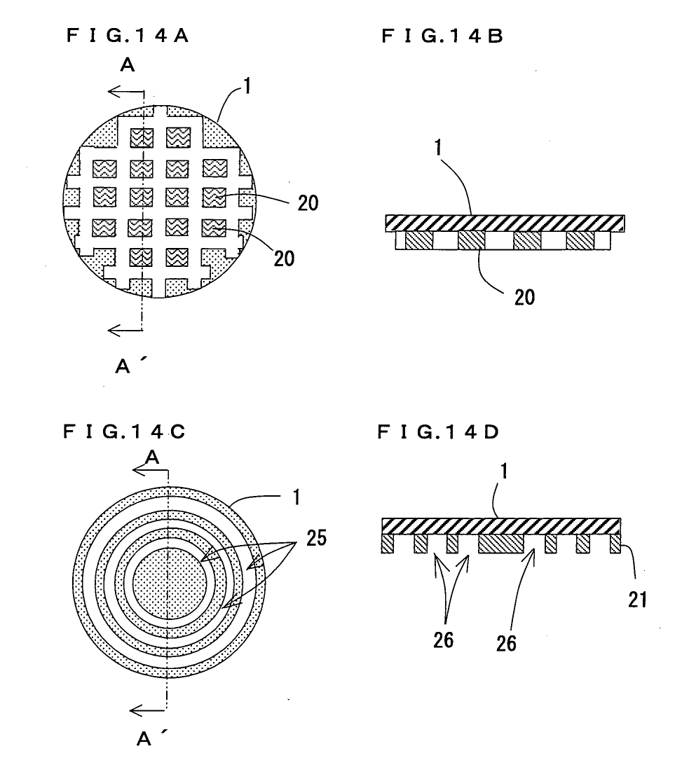

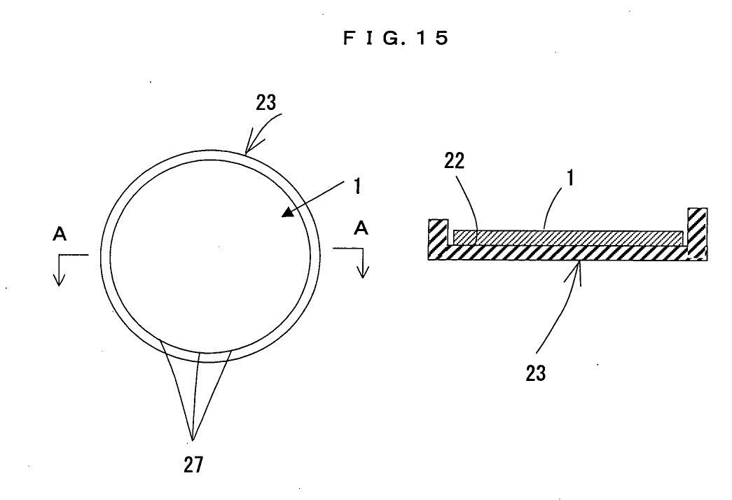

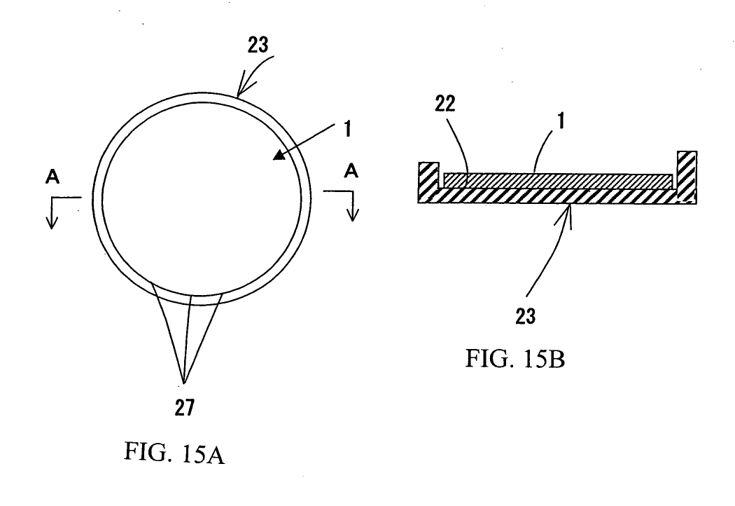

A method for fabricating a semiconductor device according to an eighth preferred embodiment of the present invention is described referring to FIGS. 14 and 15.

In the conventional method, as shown in FIGS. 14A through 14D, the wafer 1 is directly fixedly retained by means of an electrostatic chuck 20 or a vacuum chuck 21 during the process in the case of a chamber of a single sheet processing type. Reference numerals 25 and 26 respectively denote vacuum-adsorbing action parts and numeral 27 denotes a wafer lift pin protruding position.

According to the eighth embodiment, when the process, such as a diffusion step, is performed exposing a film exemplified by the BTBAS—SiN film easily damaged by the electrostatic chuck or vacuum chuck on the reverse surface, a chamber-side wafer susceptor and a loader-side wafer handler constituting the electrostatic chuck or vacuum chuck are replaced by a normal-pressure wafer susceptor and wafer handler as shown in FIG. 15.

A wafer guide ring 23 including a recessed part 22 having a substantially same shape as the wafer 1 is disposed in the wafer susceptor (not shown) and the wafer handler (not shown) The wafer 1 is housed in the recessed part 22 so that the reverse-surface side of the wafer 1 is not exposed. Thereby, the process can be advanced without causing any damage to the BTBAS—SiN film.

The wafer 1 is transferred by a normal pressure remaining housed in the wafer guide ring 23 and handed over to the wafer susceptor and wafer handler by means of a wafer lift pin (not shown) provided in the wafer susceptor.

While the invention has been described and illustrated in detail, it is to be clearly understood that this is intended be way of illustration and example only and is not to be taken by way of limitation, the spirit and scope of this invention being limited only be the terms of the following claims.

1. A method for fabricating a semiconductor device comprising:
a first step for forming a polysilicon film for a gate electrode on a semiconductor substrate;
a second step for removing a polysilicon film formed on a reverse-surface side of the semiconductor substrate in accordance with the formation of the polysilicon film;
a third step for forming an oxide film for an offset spacer on the semiconductor substrate;
a fourth step for forming a BTBAS—SiN film for at least one of a side wall and a liner on the semiconductor substrate;
a fifth step for removing a BTBAS—SiN film and an oxide film formed on the reverse-surface side of the semiconductor substrate and thereby exposing the reverse surface of the semiconductor substrate; and
a sixth step for handling the semiconductor substrate in a process or transfer of the semiconductor substrate by means of a wafer handler after the reverse surface is exposed.

2. A method for fabricating a semiconductor device as claimed in claim 1, wherein
the polysilicon film formed on the reverse-surface side of the semiconductor substrate at the same time as the formation of the polysilicon film for the gate is removed in the second step.

3. A method for fabricating a semiconductor device as claimed in claim 1, wherein
all of the BTBAS—SiN film and the oxidefilm formed on the reverse-surface side of the semiconductor substrate at the same time the formation of the BTBAS—SiN film and the oxide film are removed to thereby expose the reverse surface of the semiconductor substrate in the fifth step.

4. A method for fabricating a semiconductor device as claimed in claim 1, wherein
the wafer handler is an electrostatic chuck in the six step.

5. A method for fabricating a semiconductor device as claimed in claim 1, wherein
the wafer handler is a vacuum chuck in the six step.

6. A method for fabricating a semiconductor device comprising:
a first step for forming a polysilicon film for a gate electrode on a semiconductor substrate;
a second step for removing a polysilicon film formed on a reverse-surface side of the semiconductor substrate in response to the formation of the polysilicon film;
a third step for forming an oxide film for an offset spacer on the semiconductor substrate;
a fourth step for forming a BTBAS—SiN film for at least one of a side wall and a liner on the semiconductor substrate;
a fifth step for removing a BTBAS—SiN film formed on the reverse-surface side of the semiconductor substrate at the same time as the formation of the BTBAS—SiN film and thereby exposing an oxide film formed on the reverse-surface side of the semiconductor substrate; and
a sixth step for handling the semiconductor substrate in a process or transfer of the semiconductor substrate by means of a wafer handler after the oxide film is exposed.

7. A method for fabricating a semiconductor device as claimed in claim 6, wherein
only the BTBAS—SiN film formed on the reverse-surface side of the semiconductor substrate at the same time as the formation of the BTBAS—SiN film is removed to thereby expose the oxide film formed on the reverse-surface side of the semiconductor substrate at the same time as the formation of the oxide film for the offset spacer in the fifth step.

8. A method for fabricating a semiconductor device as claimed in claim 6, wherein
the wafer handler is an electrostatic chuck in the six step.

9. A method for fabricating a semiconductor device as claimed in claim 6, wherein
the wafer handler is a vacuum chuck in the six step.

10. A method for fabricating a semiconductor device comprising:
a first step for forming a polysilicon film for a gate electrode on a semiconductor substrate;
a second step for forming an oxide film for an offset spacer on the semiconductor substrate;
a third step for forming a BTBAS—SiN film for at least one of a side wall and a liner on the semiconductor substrate;
a fourth step for removing a BTBAS—SiN film and an oxide film formed on a reverse-surface side of the semiconductor substrate and thereby exposing a polysilicon film formed on the reverse-surface side of the semiconductor substrate; and
a fifth step for handling the semiconductor substrate in a process or transfer of the semiconductor substrate by means of a wafer handler after the polysilicon film is exposed.

11. A method for fabricating a semiconductor device as claimed in claim 10, wherein
the BTBAS—SiN film and the oxide film formed on the reverse-surface side of the semiconductor substrate at the same time as the formation of the BTBAS—SiN film and the oxide film for the offset spacer are removed to thereby expose the polysilicon film formed on the reverse-surface side of the semiconductor substrate at the same time as the formation of the polysilicon film for the gate in the fourth step.

12. A method for fabricating a semiconductor device as claimed in claim 10, wherein
the wafer handler is an electrostatic chuck in the fifth step.

13. A method for fabricating a semiconductor device as claimed in claim 10, wherein
the wafer handler is a vacuum chuck in the fifth step.

14. A method for fabricating a semiconductor device comprising:
a first step for forming an amorphous silicon film for a gate electrode on a semiconductor substrate;
a second step for forming an oxide film for an offset spacer on the semiconductor substrate;
a third step for forming a BTBAS—SiN film for at least one of a side wall and a liner on the semiconductor substrate;
a fourth step for removing a BTBAS—SiN film and an oxide film formed on a reverse-surface side of the semiconductor substrate and thereby exposing an amorphous silicon film formed on the reverse-surface side of the semiconductor substrate; and
a fifth step for handling the semiconductor substrate in a process or transfer of the semiconductor substrate by means of a wafer handler after the amorphous silicon film is exposed.

15. A method for fabricating a semiconductor device comprising:
a first step for forming an LP—SiN film for element separation on a semiconductor substrate;
a second step for forming a polysilicon film for a gate electrode on the semiconductor substrate;
a third step for removing a polysilicon film formed on a reverse-surface side of the semiconductor substrate;
a fourth step for forming an oxide film for an offset spacer on the semiconductor substrate;
a fifth step for forming a BTBAS—SiN film for at least one of a side wall and a liner on the semiconductor substrate;
a sixth step for removing a BTBAS—SiN film and an oxide film formed on the reverse-surface side of the semiconductor substrate and thereby exposing an LP—SiN film formed on the reverse-surface side of the semiconductor substrate at the same time as the formation of the LP—SiN film for the element separation; and
a seventh step for handling the semiconductor substrate in a process or transfer of the semiconductor substrate by means of a wafer handler after the LP—SiN film is exposed.

16. A method for fabricating a semiconductor device as claimed in claim 1, wherein
a removal process in the step for removing the BTBAS—SiN film and the oxide film formed on the reverse-surface side of the semiconductor substrate is performed by means of a wet etching.

17. A method for fabricating a semiconductor device as claimed in claim 14, characterized in that
the wet etching is performed by means of a stock solution of hydrofluoric acid or phosphoric acid boil.

18. A method for fabricating a semiconductor device as claimed in claim 7, wherein
a removal processing in the step for removing only the BTBAS—SiN film formed on the reverse-surface side of the semiconductor substrate is performed by means of a wet etching.

19. A method for fabricating a semiconductor device as claimed in claim 17, characterized in that
the wet etching is performed by means of a stock solution of hydrofluoric acid or phosphoric acid boil.

20. A method for fabricating a semiconductor device comprising:
a first step for forming a BTBAS—SiN film for a side wall or a liner on a semiconductor substrate and simultaneously forming a BTBAS—SiN film on a reverse-surface side of the semiconductor substrate;
a second step for handling the semiconductor substrate in a process or transfer of the semiconductor substrate by means of an electrostatic chuck or a vacuum chuck as a wafer handler; and
a third step for performing a scrubber cleaning with respect to the reverse surface of the semiconductor substrate, wherein
the semiconductor substrate and a dummy substrate are alternately mounted in a cassette capable of installing a plurality of semiconductor substrates in a constant direction providing a predetermined interval therebetween in the step for handing the semiconductor substrate by means of the electrostatic chuck or the vacuum chuck.

21. An apparatus for fabricating a semiconductor device comprising a wafer handler used for a process or transfer of a semiconductor substrate having a BTBAS—SiN film for at least one of a side wall and a liner formed thereon and a BTBAS—SiN film formed on a reverse surface thereof, wherein
the wafer handler supports four corners of the semiconductor substrate to thereby transfer the semiconductor substrate by a normal pressure.

22. An apparatus for fabricating a semiconductor device comprising a wafer susceptor and a wafer handler used for a process or transfer of a semiconductor substrate having a BTBAS—SiN film for at least one of a side wall and a liner formed thereon and a BTBAS—SiN film formed on a reverse surface thereof, wherein
a wafer guide ring including a recessed part having a substantially same shape as a wafer is disposed in the wafer susceptor and the wafer handler.
